(19) United States
(12) Patent Application Publication
(10) Pub. No.: US 2014/0206190 A1
(43) Pub. Date: Jul. 24, 2014

(54) Silicide Formation in High-Aspect Ratio Structures

(71) Applicant: INTERNATIONAL BUSINESS MACHINES CORPORATION, Armonk, NY (US)

(72) Inventors: BAOZHEN LI, SOUTH BURLINGTON, VT (US); YUN Y. WANG, POUGHQUAG, NY (US); KEITH KWONG HON WONG, WAPPINGERS FALLS, NY (US); CHIH-CHAO YANG, GLENMONT, NY (US)

(73) Assignee: INTERNATIONAL BUSINESS MACHINES CORPORATION, Armonk, NY (US)

(21) Appl. No.: 13/747,745

(22) Filed: Jan. 23, 2013

(51) Int. Cl. H01L 29/40

(52) U.S. Cl. CPC H01L 29/401
USPC 438/683; 438/682

(57) ABSTRACT

Embodiments of the present invention include methods of forming a silicide layer on a semiconductor substrate. In an exemplary embodiment, a metal layer may first be deposited above a semiconductor substrate using a chemical vapor deposition process with a metal amidinate precursor and then the semiconductor substrate may be annealed, causing the semiconductor substrate to react with the metal layer forming a metal-rich silicide layer on the semiconductor substrate. Embodiments may also include forming a low-oxygen capping layer above the metal layer prior to annealing the semiconductor substrate to protect the metal layer from oxidation. The low-oxygen capping layer may, for example, be made of titanium nitride containing less than 20 parts per million of oxygen. Embodiments may further include forming a silicide layer using the above process in a contact hole above a source/drain region of a field-effect transistor, and forming a metal contact above the silicide layer.

### BACKGROUND

The present invention relates generally to the fabrication of semiconductor devices, and more specifically to inducing channel stress in field effect transistors (FETs).

FETs may include a semiconductor substrate containing a source region and a drain region spaced apart by a channel region. A FET with n-type source region and drain region may be referred to as an nFET. A FET with p-type source region and drain region may be referred to as a pFET. The channel region may be undoped or have opposite doping than the source region and the drain region. A gate electrode may be formed above the channel region. By applying voltage to the gate electrode, the conductivity of the channel region may increase and allow current to flow from the source region to the drain region. Metal contacts may be formed to the source and drain regions to apply current to the source and drain regions.

Silicide regions, which may be more conductive than the source and drain regions, may be formed between the source and drain regions and the metal contacts to improve the flow of current through the FET. Typically, the silicide regions are formed by depositing a metal layer on the source and drain regions and then annealing the FET, causing the metal layer to react with the semiconductor material of the source and drain regions.

In some process flows, the silicide may be formed in a contact via prior to forming a metal contact in the contact via. The metal layer may be formed by depositing the metal layer in the contact via, annealing the FET, and then removing the unreacted metal. However, as feature size decreases and the aspect ratio of the contact via increases, it is increasingly difficult to deposit the metal layer using conventional physical vapor deposition (PVD) processes. In typical PVD processes, metal may tend to form thicker layers at the opening of the contact via, preventing a sufficiently thick metal layer from being formed in contact with the source/drain region at the bottom of the via where it is needed to form the silicide layer. Therefore, a chemical vapor deposition (CVD) process capable of forming conformal layers in high aspect-ratio structures may be preferable to a PVD process. The metal layer typically is made of nickel-platinum. However, there currently is no proven nickel-platinum CVD process. Therefore, a method of forming a trench silicide layer using a CVD process with an alternative to nickel-platinum is desirable.

### BRIEF SUMMARY

The present invention relates to forming silicide layers above semiconductor substrates. According to one exemplary embodiment, a silicide layer may be formed above a semiconductor substrate by first depositing a metal layer above the semiconductor substrate using a chemical vapor deposition process with a metal amidinate precursor and then annealing the semiconductor substrate causing the semiconductor substrate to react with the metal layer and form a metal-rich silicide layer on the semiconductor substrate. Exemplary metal amidinate precursors may include cobalt amidinate, nickel amidinate, and molybdenum amidinate and the metal layer formed from the metal amidinate precursor may have low oxygen content, for example less than 10 parts per million (ppm). A low-oxygen capping layer, for example a titanium nitride layer having less than 20 ppm oxygen, may be formed above the metal layer prior to annealing the semiconductor substrate to prevent oxidation of the metal layer.

According to another exemplary embodiment, a trench silicide layer may be formed above a source/drain region of a field effect transistor (FET) by etching a contact hole in an interlevel dielectric layer above the FET to expose a portion of the source/drain region, depositing a metal layer on the source/drain region in the contact hole using a chemical vapor deposition process with a metal amidinate precursor, and annealing the field effect transistor to react the source/drain region with the metal layer and form a metal-rich silicide layer on the source/drain region.

According to another exemplary embodiment, a metal contact may be formed to a source/drain region of a FET by etching a contact hole in an interlevel dielectric layer above the FET to expose a portion of the source/drain region, depositing a metal layer on the source/drain region in the contact hole using a chemical vapor deposition process with a metal amidinate precursor, depositing a capping layer above the metal layer to protect the metal layer from oxidation, and annealing the field effect transistor to react the source/drain region with the metal layer and form a metal-rich silicide layer on the source/drain region, removing the capping layer, annealing the field effect transistor to convert the metal-rich silicide layer to a silicon-rich silicide layer, lining the contact hole with a conductive liner in contact with the silicon-rich silicide layer; and filling the contact hole with a conductive material in contact with the conductive liner.

### BRIEF DESCRIPTION OF THE SEVERAL VIEWS OF THE DRAWINGS

FIG. 1 depicts forming a transistor structure, according to an embodiment of the present invention.

FIG. 2 depicts etching contact holes in the interlevel dielectric layer and the stress liner of the transistor structure, according to an embodiment of the present invention.

FIG. 3 depicts depositing a metal layer on a source/drain region in the bottom of a contact hole, according to an embodiment of the present invention.

FIG. 4 depicts depositing a capping layer above the metal layer, according to an embodiment of the present invention

FIG. 5 depicts forming a metal-rich silicide layer on the source/drain region, according to an embodiment of the present invention.

FIG. 6 depicts removing the capping layer and the metal layer from the contact hole, according to an embodiment of the present invention.

FIG. 7 depicts converting the metal-rich silicide layer to a silicon-rich silicide layer, according to an embodiment of the present invention.

FIG. 8 depicts forming a contact in the contact hole, according to an embodiment of the present invention

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

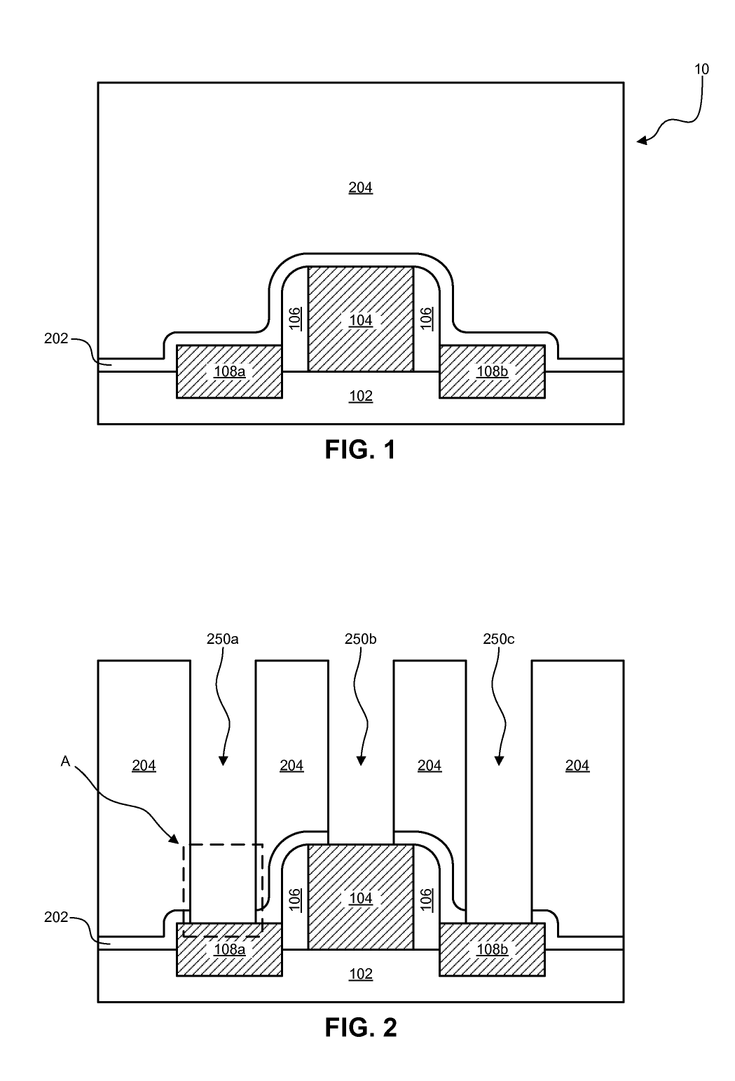

Referring to FIG. 1, a transistor structure 10 may be provided including a semiconductor substrate 102, a gate 104 above the semiconductor substrate 102, spacers 106 formed on sidewalls of the gate 104, respectively, and source/drain regions 108a and 108b formed in the semiconductor substrate 102 on opposing sides of the gate 104 adjacent to the spacers 106. A stress liner 202 and a interlevel dielectric layer (ILD) 204 may be formed above the semiconductor substrate 102.

The substrate 102 may be made of any semiconductor material including, but not limited to: silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Typically the substrate 102 may be about, but is not limited to, several hundred microns thick. For example, the substrate 102 may include a thickness ranging from 0.5 mm to about 1.5 mm. The substrate 102 may also include isolation regions to isolate the depicted transistor structure from adjacent structures (not shown). The isolation regions may be formed by any known method in the art, including, for example, etching into the substrate 102 to form trenches, and then filling the trenches with an insulating material, such as silicon dioxide. Other embodiments may include other means of isolating structures formed on the substrate 102, or may have isolation around only some of, or none of, the structures. Further, the substrate 102 may be a semiconductor-on-insulator (SOI) substrate, where the substrate 102 contains a buried insulator layer to isolate structures formed on the substrate 102.

The gate 104 may be formed by any method known in the art, including both gate-first and gate-last processes. The gate 104 may include a gate dielectric layer, a gate electrode, and a hard cap (not shown), and may be formed by any known method in the art, including both gate-first and gate-last processes, such as depositing a stack of layers on the substrate 102, masking the stack of layers using photolithography, and etching to remove unwanted material from the stack of layers (not shown). After formation of the gate 104, the spacers 106 may be formed on the sidewalls of the gate 104. The spacers 106 may be made of any suitable material including, but not limited to, silicon nitride, silicon oxide, and silicon carbide and may be approximately 2 nm to approximately 100 nm thick, but preferably approximately 2 nm to approximately 50 nm. The spacers 106 may be formed, for example, by depositing a silicon nitride layer over the gate 104 and then removing excess material using an anisotropic reactive ion etching process, such as RIE (not shown). Due to the etching process, spacers 106 may have a curved top surface on its edge opposite gate 104.

Source/drain regions 108a, 108b may be formed in the substrate 102 adjacent to the spacers 106 by any method known in the art, including doping the substrate 102 using ion implantation. In other embodiments, source/drain regions 108a, 108b may be formed by etching recess regions in substrate 102 and then filling the recess regions with semiconductor material, such as silicon-germanium or silicon-carbon, using known deposition or growth methods (not shown). In some embodiments, raised source/drain techniques may be incorporated such that source/drain regions 108a, 108b extend above the top surface of the substrate 102.

The stress liner 202 and the ILD layer 204 may be deposited above the transistor structure 10 (FIG. 1A). The stress liner 202 may be formed by depositing, using any known technique, including chemical vapor deposition (CVD) and physical vapor deposition (PVD), a silicon nitride layer above the structure of FIG. 1A. The stress liner 202 may have a thickness of approximately 5 nm to approximately 50 nm. In some embodiments, the stress liner 202 may not be present or may consist of more than one layer. The ILD layer 204 may be formed by depositing, using any known technique, including chemical vapor deposition and physical vapor deposition, an insulating layer above the stress liner 202, and then planarizing the deposited layer using, for example, chemical-mechanical planarization (CMP). The ILD layer 204 may be made of, for example, oxides, nitrides, oxynitrides, or some combination thereof, and may have a thickness of approximately 5 nm to approximately 200 nm. In some embodiments, the ILD layer 204 may consist of more than one layer.

Referring to FIG. 2, contact holes 250a-250c may be formed to exposes portions of the source/drain regions 108a, 108b and portions of the gate 104, respectively. Contact holes 250a-250c may be formed by etching the stress liner 202 and the ILD layer 204 using known anisotropic etching techniques including, for example, reactive ion etching (RIE) and plasma etching. The contact holes 250a-250c may have a horizontal width of approximately 5 nm to approximately 30 nm. In some embodiments, the sidewalls of the contact holes 250a-250c may not be fully vertical, either by intentional design choice or due to limitations of the etching process used. The contact recess regions 250a-250c may therefore have a tapered shape (not shown), narrowing as the contact holes 250a-250c approach the top surfaces of the gate 104 and the source/drain regions 108a, 108b. The contact recess regions 250a-250c may have aspect ratios of approximately 1:4 to 1:12, though greater and lesser aspect ratios are specifically contemplated.

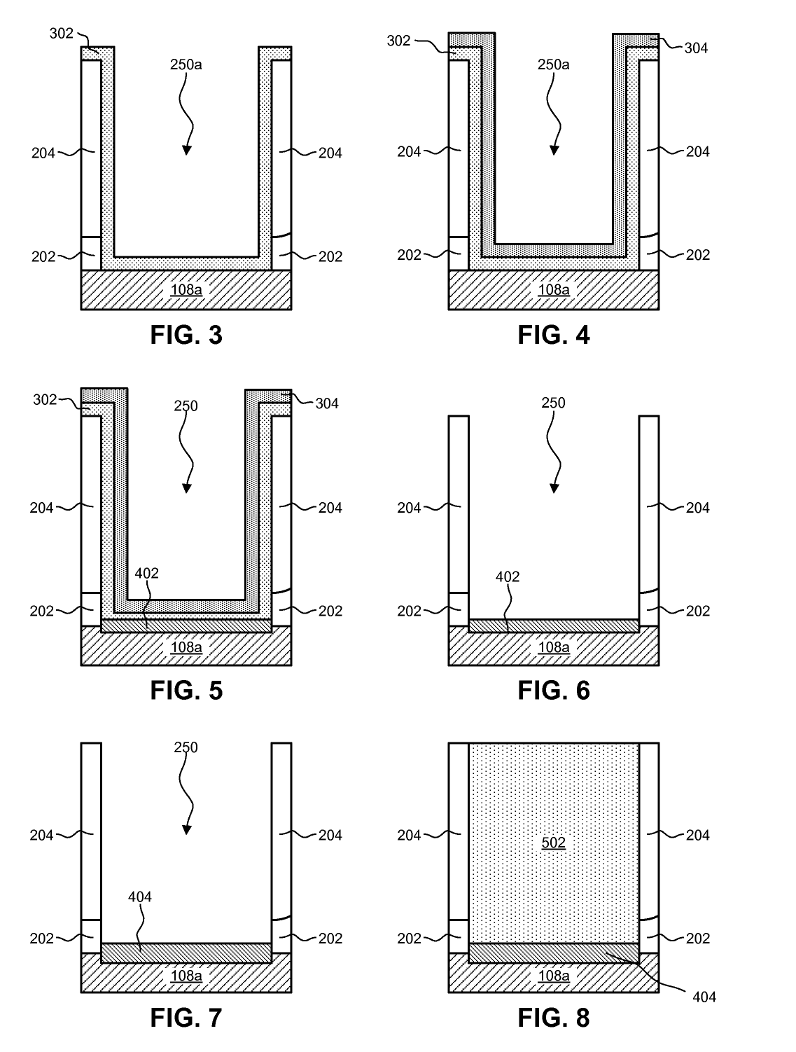

FIGS. 3-8 depict the bottom of the contact hole 250a exposing a source/drain region 108a, as indicated by section view A of FIG. 2. It will be understood that the process depicted in FIGS. 3-8 to form a silicide layer on source/drain region 108a may also be used to form silicide layers on source/drain region 108b and gate 104, in embodiments where the gate electrode of gate 104 is made of a silicon-containing material.

Referring to FIG. 3, a metal layer 302 may be deposited in the contact hole 250a in contact with the source/drain region 108a. The metal layer 302 may be formed by a CVD process using a metal amidinate precursor, preferably cobalt amidinate. The metal amidinate precursor may have the formula M(AMD)₂ and the structure

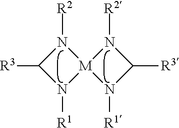

in which M is colbalt and R¹, R², R³, R^{1′}, R^{2′}, and R^{3′} are groups made from one or more non-metal atoms. In some embodiments, R¹, R², R³, R^{1′}, R^{2′}, and R^{3′} may be the same or different and may be chosen independently from hydrogen, alkyl, aryl, alkenyl, alkynyl trialkylsilyl, or fluoroalkyl groups, or other non-metal atoms or groups. In an exemplary embodiment, R¹, R³, R^{2′}, and R^{3′} may be ethyl groups and R^{1′} and R² may be t-butyl groups.

In other embodiments, the M may be other metal atoms that may be reacted with silicon to form suitable silicide layers, including for example, nickel or molybdenum. Based on the potential oxidation states of the metal atom M, the metal amidinate precursor may have the formula M(AMD)₂ and the structure

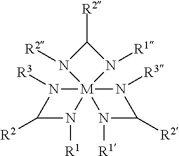

in which M is metal atom with an oxidation state of 3 and R¹, R², R³, R^{1′}, R^{2′}, R^{3′}, R^{1″}, R^{2″}, and R^{3″} are groups made from one or more non-metal atoms. In some embodiments, R¹, R², R³, R^{1′}, R^{2′}, R^{3′}, R^{1″}, R^{2″}, and R^{3″} be the same or different and may be chosen independently from hydrogen, alkyl, alkenyl, trialkylsilyl, or fluoroalkyl groups or other non-metal atoms or groups. In some embodiments, the metal amidinate precursor may also form dimers or trimers of the aforementioned monomer structures, or structures consisting of 3 or more monomer subunits.

The thermal CVD deposition process includes using the metal amidinate precursor, for example cobalt (II) amidinate in a carrier gas such as argon or helium plus hydrogen at a substrate temperature between 220-260° C. and at a pressure of about 0.05-0.15 Torr. The hydrogen reacts with metal amidinate precursor to deposit the metal layer 302. Byproducts of the reaction are carried away by the carrier gas. Specific thermal reaction conditions may be fine tuned for the specific metal amidinate precursor used. Generally, the amidinate precursor may be chosen based on the reactivity of the precursor with hydrogen, its vapor pressure and chemical stability.

Using a CVD process to form the metal layer 302 may improve coverage of the source/drain region 108a by the metal layer 302 compared to other known deposition techniques such as PVD while also improving the controllability and uniformity of the thickness of the metal layer 302. A uniform thickness is particularly beneficial in high-aspect ratio structures, where it may be difficult to achieve the necessary thickness at the bottom of the structure. Due to the lack of oxygen in the structure of the metal amidinate precursor, using the metal amidinate precursor may also decrease the oxygen content of the metal layer 302 compared to other oxygen-containing CVD precursors, such as dicobalt hexacarbonyl t-butylacetylene (CCTBA). In some embodiments, the oxygen content of the metal layer 302 may be less than approximately 10 parts per million (ppm). Reducing the oxygen content of the metal layer 302 may improve the quality of the silicide layer subsequently formed on the source/drain region 108a.

Referring to FIG. 4, a capping layer 304 may be formed in the contact hole 250a above the metal layer 302 to prevent oxidation of the metal layer 302. To prevent oxidation of the metal layer, the capping layer 304 may have a low oxygen content, preferably less than approximately 20 ppm. In some embodiments, the capping layer 304 may be formed by depositing a conformal low-oxygen titanium nitride layer above the metal layer 302 using a conformal deposition process, including, for example, CVD or atomic layer deposition (ALD). In one embodiment, the capping layer 304 may be formed using a CVD or ALD process with titanium tetrachloride and ammonia precursors to form a low-oxygen titanium nitride layer. Any other suitable low-oxygen capping layer may also be used.

Referring to FIG. 5, metal-rich silicide layers 402 may be formed at least partially on a top surface of source/drain region 108a. Metal-rich silicide layers 402 may be formed using any known silicidation technique, including, for example, annealing the structure of FIG. 4 to react the metal layer 302 with the underlying source/drain regions 108a. The annealing process may be performed by a rapid thermal annealing (RTA) process at peak temperatures ranging from approximately 300 to approximately 900 degrees Celsius, depending on the material composition of metal layer 302.

Referring to FIG. 6, the capping layer 304 (FIG. 5) and the unreacted portions of the metal layer 302 (FIG. 5) may be removed from the contact hole 250a. The capping layer 304 and the unreacted portions of the metal layer 302 may be removed using any suitable etching technique known in the art, including both wet and dry etching techniques.

Referring to FIG. 7, metal-rich silicide layers 402 (FIG. 6) may be converted into silicon-rich silicide layers 404 by, for example, a second annealing process. The second annealing process may be performed by a rapid thermal annealing (RTA) process at peak temperatures ranging from approximately 300 degrees to approximately 900 degrees Celsius, depending on the material composition of metal-rich silicide layers 402. The silicon-rich silicide layers 402 formed by the process described above in conjunction with FIGS. 1-7 may be very smooth, having a root mean square (RMS) roughness of less than approximately 1 nm.

Referring to FIG. 8, a contact 502 may be formed in the contact hole 250a (FIG. 7) above the silicon-rich silicide layer 404. The contact 502 may be formed by any method known in the art including, for example, deposition of a conductive liner (not shown) and a conductive fill in the contact hole 250a. The conductive liner may be made of, for example, titanium, tantalum, nickel, platinum, palladium, erbium, or ytterbium and formed using known metal deposition techniques including, but not limited to, CVD, physical vapor deposition (PVD) and ALD. The conductive fill may include, for example, tungsten, copper, aluminum, silver, gold, alloys thereof, and any suitable combination thereof, and may be deposited by any suitable technique, including but not limited to, for example, ALD, molecular layer deposition (MLD), CVD, in-situ radical assisted deposition, metal-organic chemical vapor deposition (MOCVD), molecular beam epitaxy (MBE), PVD, sputtering, plating, evaporation, ion beam deposition, electron beam deposition, laser assisted deposition, chemical solution deposition, or any combination thereof.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

What is claimed is:

1. A method of forming a silicide layer on a semiconductor substrate, the method comprising:
depositing a metal layer above the semiconductor substrate using a chemical vapor deposition process with a metal amidinate precursor;
annealing the semiconductor substrate causing the semiconductor substrate to react with the metal layer, wherein reacting the semiconductor substrate with the metal layer forms a metal-rich silicide layer on the semiconductor substrate;

2. The method of claim 1, wherein the metal amidinate precursor comprises cobalt amidinate, nickel amidinate, or molybdenum amidinate.

3. The method of claim 1, wherein the metal amidinate precursor has the general formula 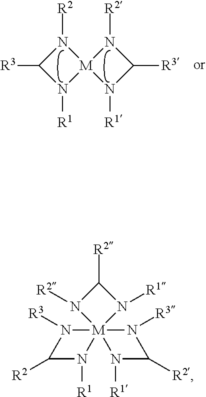
wherein M is a metal atom and R¹, R², and R³ may be chosen independently from the group comprising hydrogen, alkyl, aryl, alkenyl, alkynyl trialkylsilyl, or fluoroalkyl groups, and other non-metal atoms or groups.

4. The method of claim 1, wherein the metal layer has an oxygen content of less than approximately 10 parts per million (ppm).

5. The method of claim 1, further comprising depositing a capping layer above the metal layer prior to annealing the semiconductor substrate.

6. The method of claim 5, wherein the capping layer comprises titanium nitride.

7. The method of claim 5, wherein the capping layer has an oxygen content of less than approximately 20 ppm.

8. The method of claim 1, further comprising annealing the semiconductor substrate to convert the metal-rich silicide layer to a silicon rich silicide layer.

9. The method of claim 8, wherein the silicon-rich silicide layer has a root mean square surface roughness of less than approximately 1 nm.

10. A method of forming a trench silicide layer, the method comprising:
providing a field effect transistor comprising a semiconductor substrate, a gate on the semiconductor substrate, a source/drain region in the semiconductor substrate adjacent to the gate, and an interlevel dielectric (ILD) layer above the source/drain region;
etching the ILD to form a contact hole exposing a portion of the source/drain region;
depositing a metal layer on the source/drain region in the contact hole using a chemical vapor deposition process with a metal amidinate precursor; and
annealing the field effect transistor to react the source/drain region with the metal layer, wherein reacting the source/drain region with the metal layer forms a metal-rich silicide layer on the source/drain region.

11. The method of claim 10, wherein the metal amidinate precursor comprises cobalt amidinate, nickel amidinate, or molybdenum amidinate.

12. The method of claim 10, wherein the metal amidinate precursor has the general formula 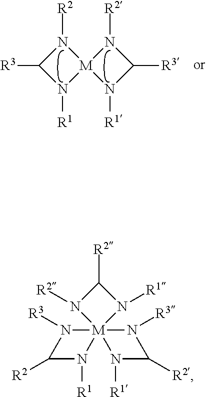
wherein M is a metal atom and R¹, R², and R³ may be chosen independently from the group comprising hydrogen, alkyl, aryl, alkenyl, alkynyl trialkylsilyl, or fluoroalkyl groups, and other non-metal atoms or groups.

13. The method of claim 10, wherein the metal layer has an oxygen content of less than approximately 10 ppm.

14. The method of claim 10, further comprising depositing a capping layer above the metal layer prior to annealing the field effect transistor.

15. The method of claim 14, wherein the capping layer comprises titanium nitride.

16. The method of claim 14, wherein the capping layer has an oxygen content of less than approximately 20 ppm.

17. The method of claim 14, further comprising:
removing the capping layer;
removing any unreacted portions of the metal layer; and
annealing the field effect transistor to convert the metal rich silicide layer to a silicon-rich silicide layer.

18. The method of claim 17, wherein the silicon-rich silicide layer has a root mean square surface roughness of less than approximately 1 nm.

19. A method of forming a metal contact to a field effect transistor comprising:
providing a field effect transistor comprising a semiconductor substrate, a gate on the semiconductor substrate, a source/drain region in the semiconductor substrate adjacent to the gate, and an interlevel dielectric (ILD) layer above the source/drain region;
etching the ILD to form a contact hole exposing a portion of the source/drain region;
depositing a metal layer on the source/drain region in the contact hole using a chemical vapor deposition process with a metal amidinate precursor;
depositing a capping layer above the metal layer to protect the metal layer from oxidation;
annealing the field effect transistor to react the source/drain region with the metal layer, wherein reacting the source/drain region with the metal layer forms a metal-rich silicide layer on the source/drain region.
removing the capping layer;
annealing the field effect transistor to convert the metal-rich silicide layer to a silicon-rich silicide layer.
lining the contact hole with a conductive liner in contact with the silicon-rich silicide layer; and
filling the contact hole with a conductive material in contact with the conductive liner.

20. The method of claim 19, wherein the metal amidinate precursor has the general formula 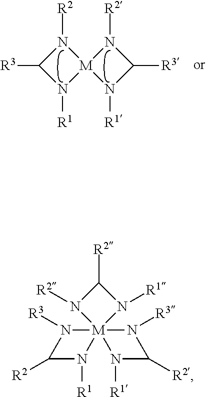
wherein M is a metal atom and R¹, R², and R³ may be chosen independently from the group comprising hydrogen, alkyl, aryl, alkenyl, alkynyl trialkylsilyl, or fluoroalkyl groups, and other non-metal atoms or groups.
